(19) United States
(12) Patent Application Publication
(10) Pub. No.: US 2025/0016915 A1
(43) Pub. Date: Jan. 9, 2025

(54) STRETCHABLE DEVICE

(71) Applicant: Japan Display Inc., Tokyo (JP)

(72) Inventors: Takumi SANO, Minato-ku (JP); Hiroumi KINJO, Minato-ku (JP)

(73) Assignee: Japan Display Inc., Tokyo (JP)

(21) Appl. No.: 18/763,223

(22) Filed: Jul. 3, 2024

(30) Foreign Application Priority Data
Jul. 4, 2023 (JP) 2023-110220

(51) Int. Cl. H05K 1/02; H05K 1/14

(52) U.S. Cl. CPC H05K 1/0283; H05K 1/14

(57) ABSTRACT

According to an aspect, a stretchable device includes: a stretchable substrate comprising a first resin layer, a resin base member, an array layer, and a second resin layer stacked in the order as listed; and a flexible printed circuit board electrically coupled to an electrical circuit included in the array layer. The resin base member includes end portions separated from each other. The electrical circuit comprises a plurality of first coupling terminals disposed on the end portions. The flexible printed circuit board comprises second coupling terminals facing the first coupling terminals. An anisotropic conductive resin layer electrically coupling the first coupling terminals to the second coupling terminals is provided between the first coupling terminals and the second coupling terminals. The first resin layer has: a first surface provided with the resin base member; and a dummy end portion provided to the first surface and disposed around the end portions.

### CROSS-REFERENCE TO RELATED APPLICATION

This application claims the benefit of priority from Japanese Patent Application No. 2023-110220 filed on Jul. 4, 2023, the entire contents of which are incorporated herein by reference.

### BACKGROUND

### 1. Technical Field

What is disclosed herein relates to a stretchable device.

### 2. Description of the Related Art

Stretchable devices include a stretchable substrate with elasticity and flexibility and a flexible printed circuit board that electrically couples an electrical circuit on the stretchable substrate to an external device. The stretchable substrate includes an array layer including the electrical circuit, a resin base member serving as a base member for the array layer, and two resin layers that sandwich the electrical circuit and the resin base member. The resin base member includes bodies arrayed in a matrix (row-column configuration) and hinges that couple the bodies to each other. As described in Japanese Patent Application Laid-open Publication No. 2021-106199 (JP-A-2021-106199), for example, the hinges have a meandering shape. When a tensile load acts on the stretchable substrate, the hinges are elongated in the tensile direction, and the stretchable substrate is stretched.

The electrical circuit included in the array layer is a load detection circuit, for example. The load detection circuit includes strain gauges disposed on the hinges. When the hinge deforms, the resistance of the strain gauge changes. By detecting the amount of change in the resistance of the strain gauge, the value of the load acting on the hinge (stretchable substrate) is calculated.

The electrical circuit includes coupling terminals and wiring that couples the coupling terminals to the load detection circuit as components other than the load detection circuit. The coupling terminals are electrically coupled to coupling terminals of the flexible printed circuit board. To provide the coupling terminals and the wiring of the electrical circuit, the resin base member includes a plurality of end portions on which the coupling terminals are disposed and a plurality of coupling hinges on which the wiring is disposed. The coupling terminals of the electrical circuit described in JP-A-2021-106199 are electrically coupled to the coupling terminals of the flexible printed circuit board by anisotropic conductive resin.

As described in JP-A-2021-106199, the end portions of the resin base member are separated from each other. In other words, the spaces between the end portions are recessed. If the anisotropic conductive resin is placed between the coupling terminals, and each of the coupling terminals is pressure-bonded to the anisotropic conductive resin, the anisotropic conductive resin is likely to move into the recesses between the end portions. In other words, the conductive particles included in the anisotropic conductive resin are also likely to move into the recesses between the end portions. An increase in the number of conductive particles that move into the recesses undesirably makes electrical coupling between the coupling terminals unstable.

For the foregoing reasons, there is a need for a stretchable device that can stabilize electrical coupling between coupling terminals.

### SUMMARY

According to an aspect, a stretchable device includes: a stretchable substrate comprising a first resin layer, a resin base member, an array layer, and a second resin layer stacked in the order as listed; and a flexible printed circuit board electrically coupled to an electrical circuit included in the array layer. The resin base member includes a plurality of end portions separated from each other. The electrical circuit comprises a plurality of first coupling terminals disposed on the end portions. The flexible printed circuit board comprises a plurality of second coupling terminals facing the first coupling terminals. An anisotropic conductive resin layer electrically coupling the first coupling terminals to the second coupling terminals is provided between the first coupling terminals and the second coupling terminals. The first resin layer has: a first surface provided with the resin base member; and a dummy end portion provided to the first surface and disposed around the end portions.

### BRIEF DESCRIPTION OF THE DRAWINGS

FIG. 1 is a schematic of a stretchable device according to an embodiment;

FIG. 2 is a schematic of a section of a stretchable substrate according to the embodiment, and more specifically a sectional view along line II-II of FIG. 1;

FIG. 3 is a plan view of a resin base member disposed on a first surface of a first resin layer according to a first embodiment, as viewed from a first thickness direction;

FIG. 4 is an enlarged view of bodies and a hinge according to the first embodiment;

FIG. 5 is an enlarged view of the bodies and the hinge according to the first embodiment on which a tensile load acts;

FIG. 6 is a circuit diagram of an electrical circuit included in an array layer according to the first embodiment;

FIG. 7 is a sectional view seen in the direction of arrow along line VII-VII of FIG. 1;

FIG. 8 is a plan view illustrating a state where an anisotropic conductive resin layer according to a second embodiment is partially removed, as viewed from the first thickness direction;

FIG. 9 is a sectional view of the stretchable device, and more specifically a sectional view along line IX-IX of FIG. 8;

FIG. 10 is a plan view of end portions and the anisotropic conductive resin layer according to a first modification, as viewed from the first thickness direction;

FIG. 11 is a plan view of the end portions and dummy end portions according to a third embodiment, as viewed from the first thickness direction; and

FIG. 12 is a plan view of the end portions and the dummy end portions according to a fourth embodiment, as viewed from the first thickness direction.

### DETAILED DESCRIPTION

Exemplary aspects (embodiments) to embody a stretchable device according to the present disclosure are described below in greater detail with reference to the accompanying drawings. The contents described in the embodiments below are not intended to limit the disclosure according to the present disclosure. Components described below include components easily conceivable by those skilled in the art and components substantially identical therewith. Furthermore, the components described below may be appropriately combined. What is disclosed herein is given by way of example only, and appropriate modifications made without departing from the spirit of the present disclosure and easily conceivable by those skilled in the art naturally fall within the scope of the present disclosure. To simplify the explanation, the drawings may possibly illustrate the width, the thickness, the shape, and other elements of each unit more schematically than the actual aspect. These elements, however, are given by way of example only and are not intended to limit interpretation of the present disclosure. In the present specification and the drawings, components similar to those previously described with reference to previous drawings are denoted by the same reference numerals, and detailed explanation thereof may be appropriately omitted.

When the term “on” is used to describe an aspect where a first structure is disposed on or above a second structure in the present specification and the claims, it includes both of the following cases unless otherwise noted: a case where the first structure is disposed on and in contact with the second structure, and a case where the first structure is disposed above the second structure with still another structure interposed therebetween.

### First Embodiment

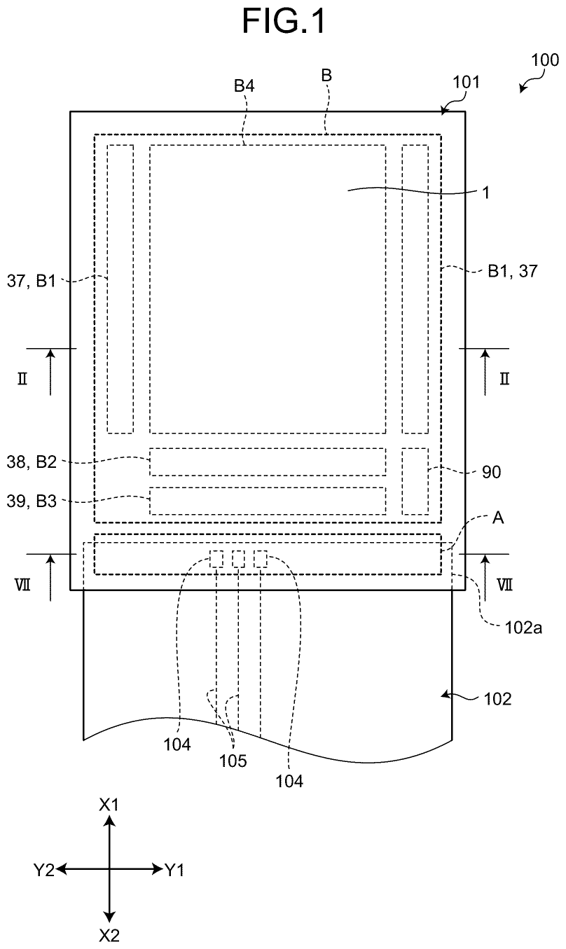

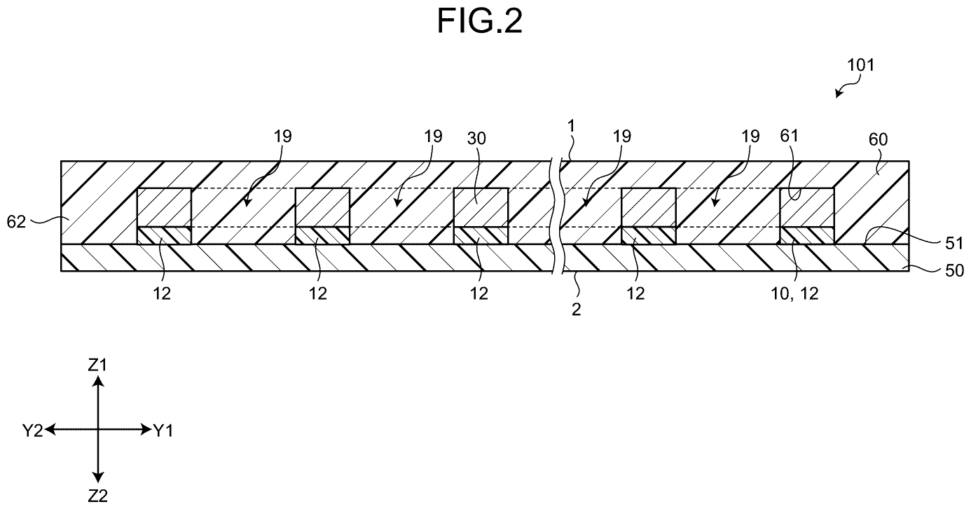

FIG. 1 is a schematic of a stretchable device according to an embodiment. As illustrated in FIG. 1, a stretchable device 100 includes a stretchable substrate 101 and a flexible printed circuit board 102. The stretchable substrate 101 and the flexible printed circuit board 102 are each formed in a flat plate shape. The stretchable substrate 101 has a surface 1 and a back surface 2 (not illustrated in FIG. 1, and refer to FIG. 2) facing opposite to each other.

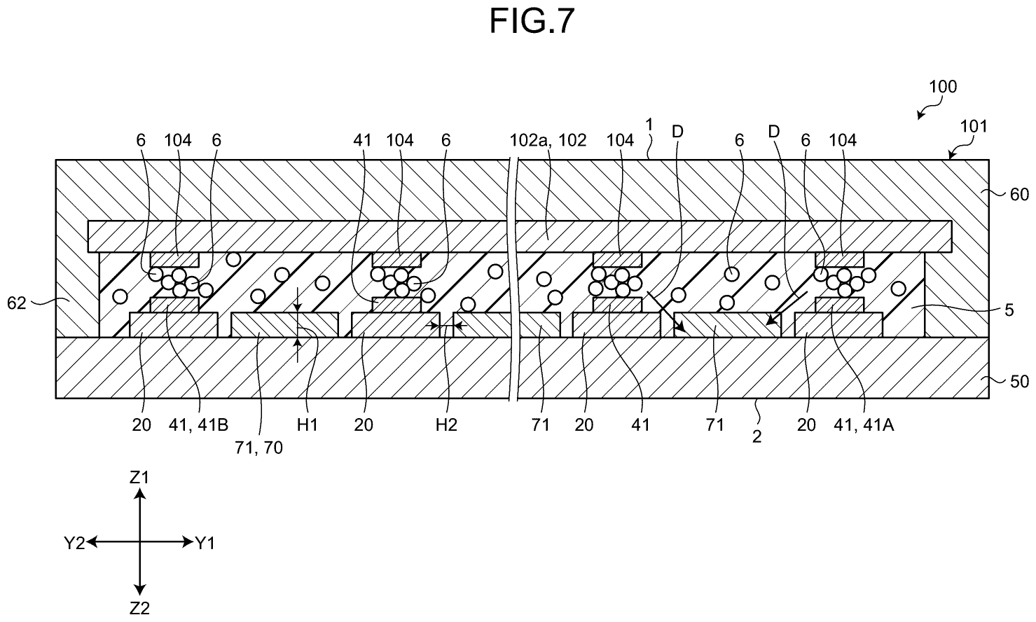

The stretchable substrate 101 and the flexible printed circuit board 102 are each formed in a rectangular (quadrilateral) shape in plan view. A first end 102a of the flexible printed circuit board 102 is bonded to the stretchable substrate 101 by an anisotropic conductive resin layer 5 (refer to FIG. 7). With this configuration, the stretchable device 100 is long in the direction in which the stretchable substrate 101 and the flexible printed circuit board 102 are disposed.

The direction parallel to the surface 1 and in which the stretchable substrate 101 and the flexible printed circuit board 102 are disposed is hereinafter referred to as a longitudinal direction. With respect to the longitudinal direction, the direction in which the stretchable substrate 101 is disposed when viewed from the flexible printed circuit board 102 is referred to as a first longitudinal direction X1, and the direction opposite to the first longitudinal direction X1 is referred to as a second longitudinal direction X2. The direction parallel to the surface 1 and intersecting the longitudinal direction is referred to as an intersecting direction.

FIG. 2 is a schematic of a section of the stretchable substrate according to the embodiment, and more specifically a sectional view along line II-II of FIG. 1. As illustrated in FIG. 2, the stretchable substrate 101 includes a first resin layer 50, a resin base member 10, an array layer 30, and a second resin layer 60 stacked in the order as listed.

The direction in which the first resin layer 50, the resin base member 10, the array layer 30, and the second resin layer 60 are stacked is hereinafter referred to as a thickness direction. With respect to the thickness direction, the direction in which the second resin layer 60 is disposed when viewed from the first resin layer 50 is referred to as a first thickness direction Z1, and the direction opposite to the first thickness direction Z1 is referred to as a second thickness direction Z2. The view of the stretchable substrate 101 from the first thickness direction Z1 is referred to as plan view. With respect to the intersecting direction, when the stretchable substrate 101 is viewed in plan view, the direction in which the right side is positioned is referred to as a first intersecting direction Y1, and the direction in which the left side is positioned is referred to as a second intersecting direction Y2.

The first resin layer 50 and the second resin layer 60 are made of resin and have insulating, elastic, and flexible properties. The resin used as the first resin layer 50 and the second resin layer 60 is polyimide, for example. The first resin layer 50 and the second resin layer 60 according to the present disclosure are not limited to polyimide. They may be acrylic resin, epoxy resin, urethane resin, or the like and are not particularly limited.

The first resin layer 50 and the second resin layer 60 extend in the longitudinal direction and the intersecting direction and are formed in a plate shape. The surface of the first resin layer 50 in the second thickness direction Z2 serves as the back surface 2 of the stretchable substrate 101. The first resin layer 50 has a first surface 51 facing the first thickness direction Z1. The resin base member 10 is stacked on the first surface 51.

The surface of the second resin layer 60 in the first thickness direction Z1 serves as the surface 1 of the stretchable substrate 101. A surface 61 of the second resin layer 60 in the second thickness direction Z2 covers the array layer 30 from the first thickness direction Z1. The ends of the second resin layer 60 in the longitudinal direction and in the intersecting direction are provided with a frame part 62 that protrudes in the second thickness direction Z2 from the surface 61. The frame part 62 has an annular shape in plan view and surrounds the outer periphery of the resin base member 10 and the array layer 30. The surface of the frame part 62 in the second thickness direction adheres to the first surface 51 of the first resin layer 50. Thus, the first resin layer 50 and the second resin layer 60 cooperate to serve as a housing that accommodates the resin base member 10 and the array layer 30.

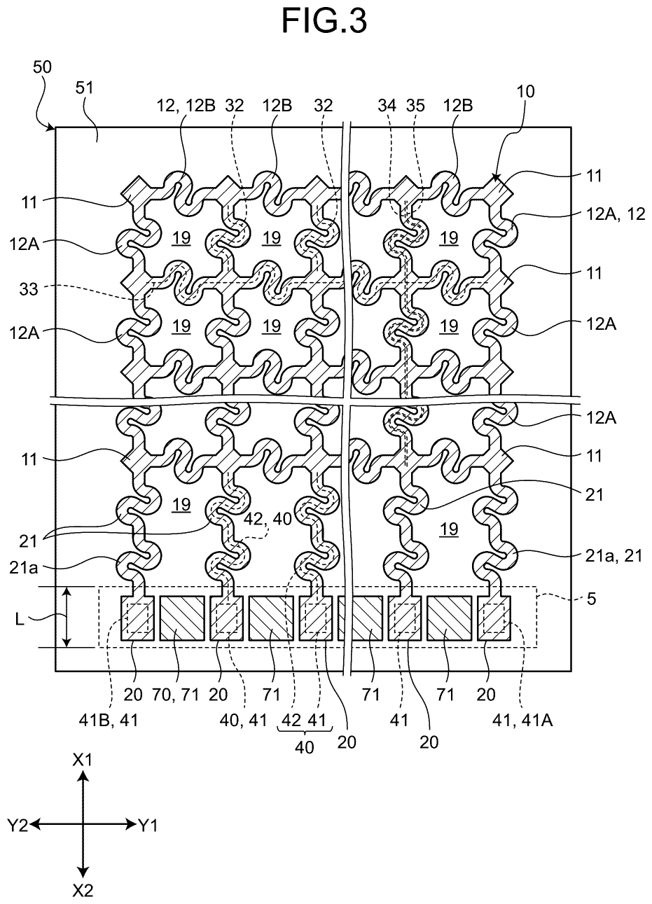

FIG. 3 is a plan view of the resin base member disposed on the first surface of the first resin layer according to a first embodiment, as viewed from the first thickness direction. In FIG. 3, the resin base member 10 is hatched to make it easy to see the resin base member 10. The resin base member 10 is bonded to the first surface 51 of the first resin layer 50. The resin base member 10 has elastic, flexible, and insulating properties. The resin base member 10 is made of resin material, such as polyimide.

The resin base member 10 includes a plurality of bodies 11, a plurality of hinges 12 extending while meandering, a plurality of end portions 20 having a rectangular shape in plan view, and coupling hinges 21 extending from the end portions 20 while meandering. The end portions 20 and the coupling hinges 21 are disposed at the end of the first surface 51 in the second longitudinal direction X2 (refer to the area enclosed by dashed line A in FIG. 1). By contrast, the bodies 11 and the hinges 12 are disposed on the first surface 51 in the first longitudinal direction X1 with respect to the end of the first surface 51 in the second longitudinal direction X2 (refer to the area enclosed by dashed line B in FIG. 1).

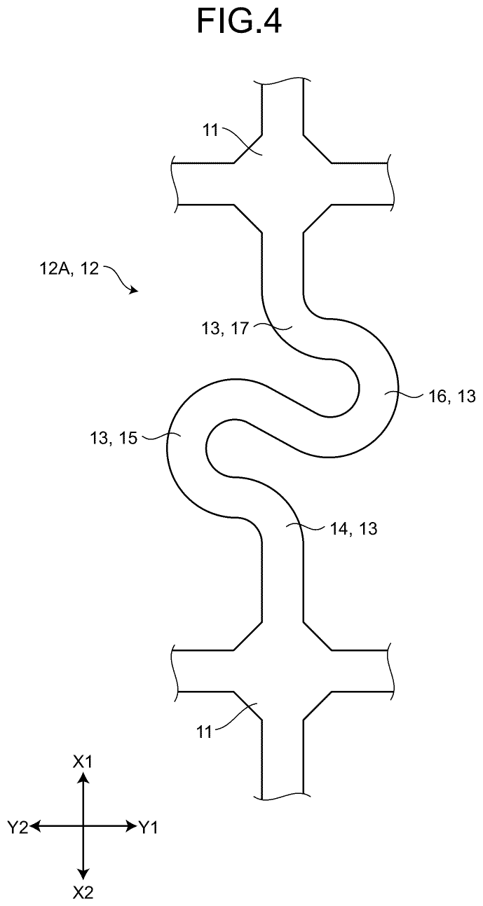

FIG. 4 is an enlarged view of the bodies and the hinge according to the first embodiment. The body 11 has a quadrilateral (square) shape in plan view. The body 11 is disposed with its four corners facing the longitudinal direction and the intersecting direction. The bodies 11 are arrayed in the longitudinal direction and the intersecting direction and are separated from one another. The shape of the body 11 according to the present disclosure in plan view is not limited to a quadrilateral shape and may be circular or other polygonal shapes.

As illustrated in FIG. 3, the hinges 12 include longitudinal hinges 12A extending in the longitudinal direction and lateral hinges 12B extending in the intersecting direction. When the longitudinal hinge 12A is rotated by 90 degrees, it has the same shape as that of the lateral hinge 12B in plan view. In the following explanation of the hinge 12, the longitudinal hinge 12A is described as a representative example, and description of the lateral hinge 12B is omitted.

As illustrated in FIG. 4, the longitudinal hinge 12A has four bends 13 and extends in the longitudinal direction while meandering. Each bend 13 according to the present embodiment has an arc shape. The bend according to the present disclosure does not necessarily have an arc shape and may have an angular shape. The number of bends is not limited to four.

The four bends 13 are a first arc 14, a second arc 15, a third arc 16, and a fourth arc 17 arranged in the order as listed, from the second longitudinal direction X2. The first arc 14 and the fourth arc 17 each form a quadrant and are bent at 90 degrees. The second arc 15 and the third arc 16 each form a semi-circular arc and are bent at 180 degrees.

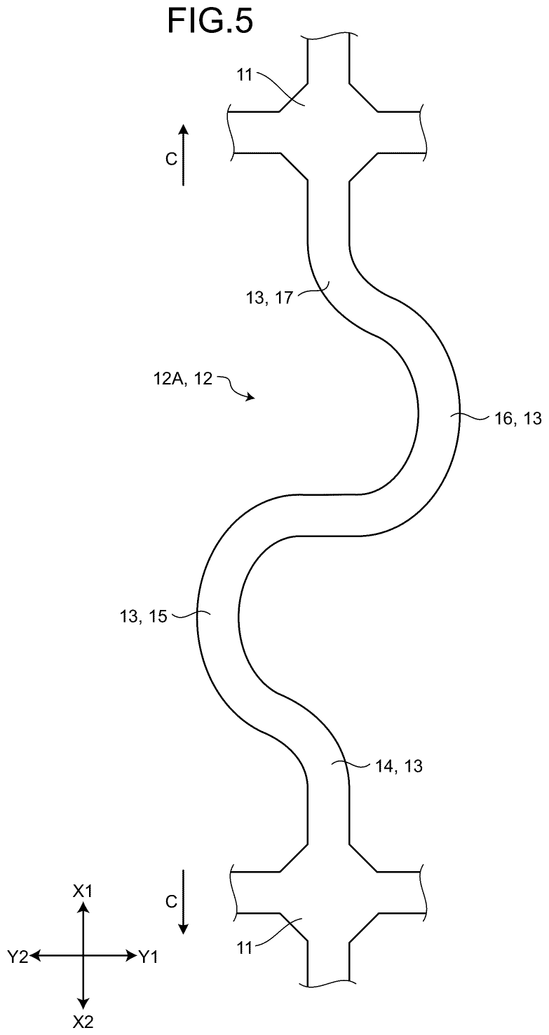

FIG. 5 is an enlarged view of the bodies and the hinge according to the first embodiment on which a tensile load acts. As illustrated in FIG. 5, when a tensile load in the longitudinal direction (refer to arrow C in FIG. 5) acts on the longitudinal hinge 12A, the first arc 14, the second arc 15, the third arc 16, and the fourth arc 17 are each deformed such that the curvature decreases. As a result, the distance from one end of the longitudinal hinge 12A to the other increases, and the bodies 11 move away from each other. When a compressive load in the longitudinal direction acts on the longitudinal hinge 12A, the first arc 14, the second arc 15, the third arc 16, and the fourth arc 17 are each deformed such that the curvature increases, which is not specifically illustrated. As a result, the distance from one end of the longitudinal hinge 12A to the other decreases, and the bodies 11 move closer to each other.

As illustrated in FIG. 3, the part surrounded by the four hinges 12 disposed in an annular (square) shape is a hollow portion 19 that passes through the resin base member 10 in the thickness direction. In other words, the resin base member 10 has a plurality of hollow portions 19.

As illustrated in FIG. 2, the hollow portion 19 is filled with the second resin layer 60. With this configuration, the stretchable substrate 101 has low rigidity in the area overlapping the hollow portion 19 and has elasticity and bendability (stretchability). When a load acts on the stretchable substrate 101, the hinges 12 deform. The bodies 11 hardly deform, thereby reducing damage to functional elements (transistors 36 according to the present embodiment) stacked on the bodies 11.

While the hollow portion 19 according to the present embodiment is filled with the second resin layer 60, the hollow portion 19 according to the present disclosure may be filled with the first resin layer 50. Alternatively, the hollow portion 19 may be filled with the first resin layer 50 and the second resin layer 60. Still alternatively, the hollow portion 19 may be filled with resin other than the first resin layer 50 or the second resin layer 60. Still alternatively, the hollow portion 19 may be a space provided with nothing.

As illustrated in FIG. 3, the end portion 20 is formed in a rectangular shape in plan view and has four sides. The end portion 20 is disposed with its four sides facing in the longitudinal direction and the intersecting direction. A plurality of end portions 20 are equally spaced in the intersecting direction.

The coupling hinge 21 extends in the longitudinal direction. The end of the coupling hinge 21 in the first longitudinal direction X1 is coupled to the body 11. The end of the coupling hinge 21 in the second longitudinal direction X2 is coupled to the end portion 20. Similarly to the hinge 12, the coupling hinge 21 has a plurality of bends 21a and extends in the longitudinal direction while meandering.

The space between the coupling hinges 21 is the hollow portion 19 and is filled with the second resin layer 60. When a load is applied to the stretchable substrate 101, the coupling hinges 21 also deform. In other words, the stretchable substrate 101 has elasticity and flexibility also at the end in the second longitudinal direction X2 (refer to the area enclosed by dashed line A in FIG. 1).

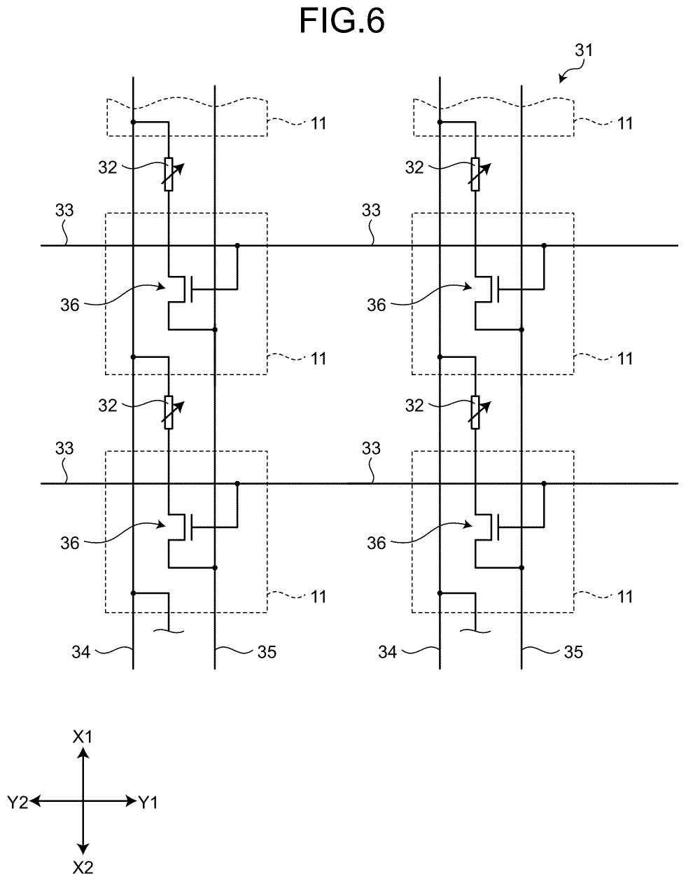

As illustrated in FIG. 2, the array layer 30 is provided on the surface of the resin base member 10 in the first thickness direction Z1. The array layer 30 includes a plurality of insulating layers (not illustrated) stacked in the thickness direction and an electrical circuit insulated from the outside by the insulating layers. The electrical circuit according to the present embodiment includes a load detection circuit 31 (refer to FIG. 6) and coupling wiring 40 (refer to FIG. 3) that transmits the results of the load detection circuit 31 to an external device. As illustrated in FIG. 3, the coupling wiring 40 is provided to the end portion 20 and the coupling hinge 21. In other words, the coupling wiring 40 is disposed at the end of the stretchable substrate 101 in the second longitudinal direction X2 (refer to the area enclosed by dashed line A in FIG. 1). The load detection circuit 31 is provided to the bodies 11 and the hinges 12. Therefore, the load detection circuit 31 is disposed in the first longitudinal direction X1 with respect to the end of the stretchable substrate 101 in the second longitudinal direction X2 (refer to the area enclosed by dashed line B in FIG. 1).

FIG. 6 is a circuit diagram of the electrical circuit included in the array layer according to the first embodiment. As illustrated in FIG. 6, the load detection circuit 31 includes strain gauges 32, gate lines 33, signal lines 34, power supply lines 35, transistors 36, gate line drive circuits 37 (refer to FIG. 1), a signal line selection circuit 38 (refer to FIG. 1), a power supply line selection circuit 39 (refer to FIG. 1), and a drive IC 90 (refer to FIG. 1).

As illustrated in FIG. 3, the strain gauge 32 is disposed at and extends along the longitudinal hinge 12A. Therefore, when the longitudinal hinge 12A deforms, the strain gauge 32 also deforms, and the resistance of the strain gauge 32 changes. While the strain gauge 32 according to the present embodiment is disposed at the longitudinal hinge 12A, for example, the strain gauge 32 according to the present disclosure may be disposed at the lateral hinge 12B.

Not all the longitudinal hinges 12A are provided with the strain gauges 32. Specifically, among all the longitudinal hinges 12A, the longitudinal hinges 12A disposed on both sides in the intersecting direction (refer to the areas enclosed by dashed lines B1 in FIG. 1) are provided with no strain gauge 32. Among all the longitudinal hinges 12A, the longitudinal hinges 12A disposed at the end in the second longitudinal direction X2 (refer to the areas enclosed by dashed lines B2 and B3 in FIG. 1) are provided with no strain gauge 32. Therefore, among the longitudinal hinges 12A, only the longitudinal hinges 12A disposed in the area enclosed by dashed line B4 in FIG. 1 are provided with the strain gauges 32. The area provided with the strain gauges 32 is hereinafter referred to as a detection region B4.

As illustrated in FIG. 3, the gate line 33 is disposed over a plurality of lateral hinges 12B and a plurality of bodies 11, thereby extending in the intersecting direction in the detection region B4. The signal line 34 and the power supply line 35 are disposed over a plurality of longitudinal hinges 12A and a plurality of bodies 11, thereby extending in the longitudinal direction in the detection region B4.

The transistor 36 is provided to each of the bodies 11 disposed in the detection region B4. As illustrated in FIG. 6, the gate electrode of the transistor 36 is coupled to the gate line 33. The drain electrode of the transistor 36 is coupled to the power supply line 35. The source electrode of the transistor 36 is coupled to the signal line 34 via the strain gauge 32.

The gate line drive circuit 37 is a circuit that drives a plurality of gate lines 33 based on control signals supplied from the drive integrated circuit (IC) 90. The gate line drive circuits 37 are provided to a plurality of bodies 11 and a plurality of hinges 12 disposed on opposite sides in the intersecting direction (refer to the areas enclosed by dashed lines B1 in FIG. 1) out of all bodies 11 and all hinges 12.

The signal line selection circuit 38 is a switch circuit that sequentially or simultaneously selects a plurality of signal lines 34 based on control signals supplied from the drive IC 90. As illustrated in FIG. 1, the signal line selection circuit 38 is provided to a plurality of bodies 11 and a plurality of hinges 12 disposed at the end in the second longitudinal direction X2 (refer to the area enclosed by dashed line B2 in FIG. 1) out of all bodies 11 and all hinges 12.

The power supply line selection circuit 39 is a switch circuit that sequentially or simultaneously selects a plurality of power supply lines based on control signals supplied from the drive IC 90. As illustrated in FIG. 1, the power supply line selection circuit 39 is provided to a plurality of bodies 11 and a plurality of hinges 12 disposed at the end in the second longitudinal direction X2 (refer to the area enclosed by dashed line B3 in FIG. 1) out of all bodies 11 and all hinges 12.

The drive IC 90 is a control device that transmits various signals to the gate line drive circuit 37, the signal line selection circuit 38, and the power supply line selection circuit 39 to drive each of them. The drive IC 90 according to the present embodiment is provided to the resin base member 10 of the stretchable substrate 101. Specifically, the drive IC 90 is disposed on one body 11 positioned closest to the end in the second longitudinal direction X2 and the end in the first intersecting direction Y1 (refer to FIG. 1) out of the bodies 11. The body 11 provided with the drive IC 90 is larger in plan view than the other bodies 11. The drive IC 90 according to the present disclosure is not necessarily disposed at the position described in the first embodiment. The drive IC 90 may not be mounted on the stretchable substrate 101 but may be provided to an external device.

An example of the operation of the load detection circuit 31 is described below. As illustrated in FIG. 6, when one gate line 33 selected by the gate line drive circuit 37 is driven, a plurality of transistors 36 arrayed in the intersecting direction and coupled to the gate line 33 are turned ON. A signal (e.g., voltage value) is transmitted to the strain gauge 32 via the transistor 36 from one or a plurality of power supply lines 35 selected by the power supply line selection circuit 39.

If the longitudinal hinge 12A is not deformed, the voltage value of the signal flowing through the strain gauge 32 is a predetermined value. By contrast, if the longitudinal hinge 12A is deformed, the resistance of the strain gauge 32 changes. In other words, the signal flowing through the strain gauge 32 indicates a voltage value different from the predetermined value. A signal (detection result) output from the strain gauge 32 flows to the signal line 34. The signal (detection result) is transmitted from the signal line 34 selected by the signal line selection circuit 38 toward the coupling wiring 40 (refer to FIG. 3).

As illustrated in FIG. 3, the coupling wiring 40 includes a plurality of first coupling terminals 41 disposed on the end portions 20 and a plurality of wiring lines 42 disposed on the coupling hinges 21. The first coupling terminal 41 is formed in a rectangular shape in plan view. While the first coupling terminal 41 according to the present embodiment is smaller than the end portion 20 in plan view, and the end portion 20 extends from the periphery of the first coupling terminal 41, the first coupling terminal 41 according to the present disclosure may have the same size as that of the end portion 20.

The wiring line 42 extends in the longitudinal direction. The end of the wiring line 42 in the first longitudinal direction X1 is coupled to the load detection circuit 31. The end of the wiring line 42 in the second longitudinal direction X2 is coupled to the first coupling terminal 41.

FIG. 7 is a sectional view seen in the direction of arrow along line VII-VII of FIG. 1. As illustrated in FIG. 7, the anisotropic conductive resin layer 5 is provided in the first thickness direction Z1 with respect to the first coupling terminals 41. The anisotropic conductive resin layer 5 is a resin in which conductive microparticles (hereinafter referred to as conductive particles 6) are dispersed. As illustrated in FIG. 3, the length L of the anisotropic conductive resin layer 5 in the planar direction is longer than the lengths of the first coupling terminal 41 and the end portion 20 in the planar direction. Therefore, the anisotropic conductive resin layer 5 expands from the end portions 20 in the first longitudinal direction X1 and the second longitudinal direction X2 and is bonded to the first surface 51 of the first resin layer 50.

The anisotropic conductive resin layer 5 extends in the intersecting direction. The end of the anisotropic conductive resin layer 5 in the first intersecting direction Y1 extends in the first intersecting direction Y1 with respect to a first coupling terminal 41A disposed closest to the end in the first intersecting direction Y1 out of the first coupling terminals 41. The end of the anisotropic conductive resin layer 5 in the second intersecting direction Y2 extends in the second intersecting direction Y2 with respect to a first coupling terminal 41B disposed closest to the end in the second intersecting direction Y2 out of the first coupling terminals 41. Thus, the anisotropic conductive resin layer 5 is disposed over the first coupling terminals 41, the end portions 20, and the part around the end portions 20 (first surface 51 of the first resin layer 50).

The flexible printed circuit board 102 is a coupling component for electrically coupling the stretchable device 100 to an external device. As illustrated in FIG. 1, the flexible printed circuit board 102 includes second coupling terminals 104 and wiring lines 105. The second coupling terminals 104 are disposed at the first end 102a of the flexible printed circuit board 102. The wiring lines 105 extend in the second longitudinal direction X2 from the second coupling terminals 104.

As illustrated in FIG. 7, the first end 102a of the flexible printed circuit board 102 is disposed between the anisotropic conductive resin layer 5 and the second resin layer 60 and bonded to them. The second coupling terminals 104 are provided to the surface of the flexible printed circuit board 102 in the second thickness direction Z2 and face the first coupling terminals 41.

The method of forming the anisotropic conductive resin layer 5 according to the present embodiment is as follows: the anisotropic conductive resin layer 5 in which the resin is melted is applied to each of the first coupling terminals 41, the end portions 20, and the part around the end portions 20 (first surface 51 of the first resin layer 50). Next, the flexible printed circuit board 102 is stacked on the anisotropic conductive resin layer 5 in the first thickness direction Z1 and is pressed in the second thickness direction Z2. As a result, each of the first coupling terminals 41, the end portions 20, the part around the end portions 20 (first surface 51 of the first resin layer 50), and the flexible printed circuit board 102 (including the second coupling terminals 104) are pressure-bonded to the anisotropic conductive resin layer 5. Subsequently, the resin is cured to form the anisotropic conductive resin layer 5.

When the flexible printed circuit board 102 is pressed (pressure-bonded), the conductive particles 6 are crushed between the first coupling terminal 41 and the second coupling terminal 104. The crushed conductive particles 6 contact each other and constitute a conductive path in the thickness direction. These conductive particles 6 electrically couple the first coupling terminal 41 to the second coupling terminal 104.

As illustrated in FIGS. 3 and 7, the first surface 51 of the first resin layer 50 is provided with a dummy end portion 70. The dummy end portion 70 is disposed around the end portions 20. The dummy end portion 70 is made of resin such as polyimide, inorganic material, or organic material. The dummy end portion 70 according to the first embodiment includes rectangular first dummy end portions 71 disposed between the end portions 20. The size H1 (refer to FIG. 7) of the first dummy end portion 71 in the thickness direction is equal to that of the end portion 20.

If the dummy end portion 70 is not provided, the space between the end portions 20 is a recess with the first surface 51 as the bottom. Therefore, when the flexible printed circuit board 102 is pressure-bonded to the anisotropic conductive resin layer 5, the anisotropic conductive resin layer 5 is likely to move into the recess between the end portions 20 (refer to arrow D in FIG. 7).

In the configuration according to the first embodiment described above, the space between the end portions 20 is filled with the first dummy end portion 71. When the flexible printed circuit board 102 is pressure-bonded to the anisotropic conductive resin layer 5, the anisotropic conductive resin layer 5 is less likely to move to the space between the end portions 20. In other words, the conductive particles 6 in the anisotropic conductive resin layer 5 are prevented from moving to the space between the end portions 20. Therefore, the reduction in the number of conductive particles 6 that electrically couple the first coupling terminal 41 to the second coupling terminal 104 is suppressed. As a result, the electrical coupling between the first coupling terminal 41 and the second coupling terminal 104 is stabilized.

As illustrated in FIG. 7, the first dummy end portion 71 according to the first embodiment is separated from the end portion 20, and thus a gap is provided between the first dummy end portion 71 and the end portion 20. The size H2 of the gap between the first dummy end portion 71 and the end portion 20 is smaller than the diameter of the conductive particles 6. With this configuration, the conductive particles 6 are less likely to move to the space between the first dummy end portion 71 and the end portion 20. The diameter of the conductive particles 6 is typically 3 μm. Therefore, the gap between the first dummy end portion 71 and the end portion 20 is preferably smaller than 3 μm.

While the first embodiment has been described above, the present disclosure is not limited to the example described in the first embodiment. For example, the size H1 of the dummy end portion 70 in the thickness direction may be larger or smaller than that of the end portion 20 and is not particularly limited. Next, other embodiments are described. The following mainly describes the differences from the first embodiment.

### Second Embodiment

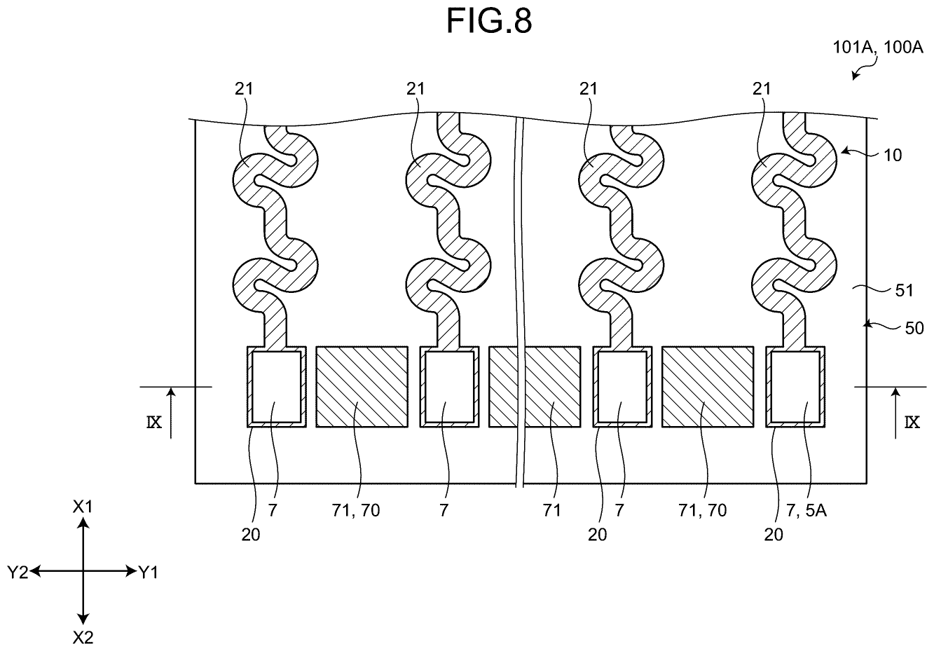

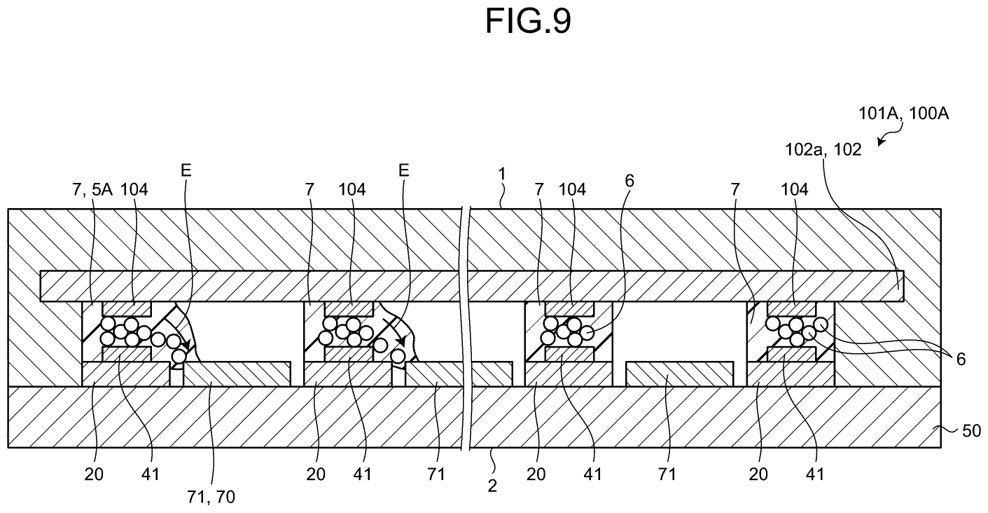

FIG. 8 is a plan view illustrating a state where the anisotropic conductive resin layer according to a second embodiment is partially removed, as viewed from the first thickness direction. FIG. 9 is a sectional view of the stretchable device, and more specifically a sectional view along line IX-IX of FIG. 8. As illustrated in FIGS. 8 and 9, a stretchable substrate 101A of a stretchable device 100A according to the second embodiment is different from the first embodiment in that an anisotropic conductive resin layer 5A is disposed only on the first coupling terminals 41 (not illustrated in FIG. 8, and refer to FIG. 9) and the end portions 20 in the first thickness direction Z1 and is not disposed around the end portions 20 (first surface 51 of the first resin layer 50). In other words, the anisotropic conductive resin layer 5A according to the second embodiment includes a plurality of divided anisotropic conductive resin layers 7. To make the divided anisotropic conductive resin layer 7 easy to see in FIG. 8, the outer periphery of the divided anisotropic conductive resin layer 7 is illustrated smaller than that of the end portion 20.

The method of forming the anisotropic conductive resin layer 5A according to the second embodiment is as follows: a sheet-like anisotropic conductive resin in which the resin is cured is stacked on each of the first coupling terminals 41, the end portions 20, and the part around the end portions 20 (first surface 51 of the first resin layer 50). The sheet-like anisotropic conductive resin has the same size as that of the anisotropic conductive resin layer 5 according to the first embodiment (refer to FIG. 3). Subsequently, part of the sheet-like anisotropic conductive resin overlapping the part around the end portions 20 (first surface of the first resin layer) in the thickness direction is removed by a laser, for example. As a result, the sheet-like anisotropic conductive resin is divided and provided only on the first coupling terminals 41 and the end portions 20.

Next, the resin of the anisotropic conductive resin is melted, and the flexible printed circuit board 102 is pressure-bonded to the anisotropic conductive resin from the first thickness direction Z1. Subsequently, the resin is cured to form a plurality of divided anisotropic conductive resin layers 7. When the flexible printed circuit board 102 is pressure-bonded, the conductive particles 6 are crushed between the first coupling terminal 41 and the second coupling terminal 104. The crushed conductive particles 6 contact each other and constitute a conductive path in the thickness direction. As a result, the first coupling terminal 41 and the second coupling terminal 104 are electrically coupled each other.

When the flexible printed circuit board 102 is pressure-bonded to the anisotropic conductive resin layer 5A according to the second embodiment, the anisotropic conductive resin layer 5A is crushed in the second thickness direction Z2. Part of the anisotropic conductive resin layer 5A flows from the first coupling terminal 41 and the end portion 20 to the space between the end portions 20 (refer to arrow E in FIG. 9). Part of the anisotropic conductive resin layer 5A, however, is less likely to move to the space between the end portions 20 because the space between the end portions 20 is filled with the dummy end portion 70 (first dummy end portion 71). Therefore, also in the second embodiment, the reduction in that the number of conductive particles 6 that electrically couple the first coupling terminal 41 to the second coupling terminal 104 is suppressed.

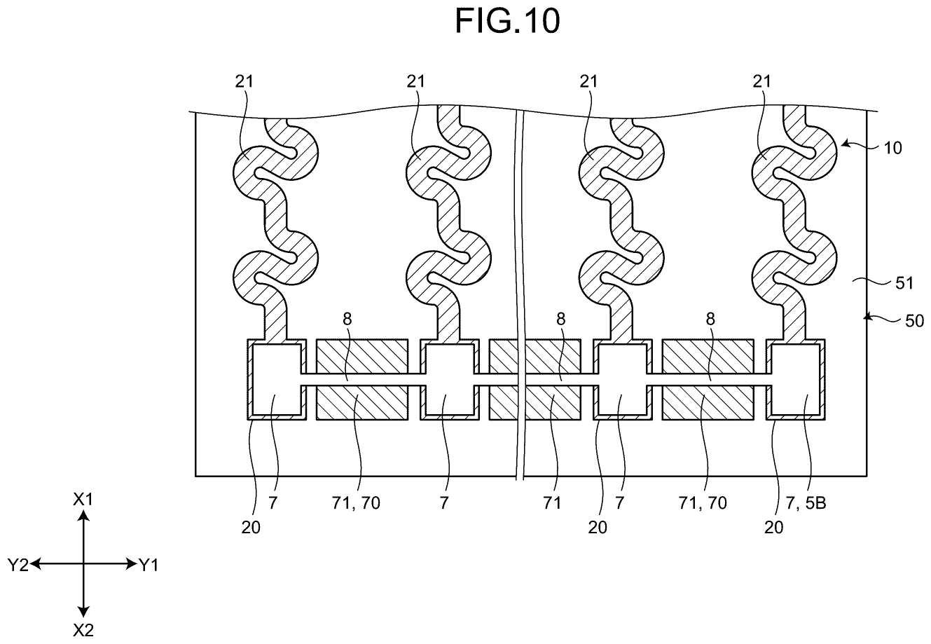

FIG. 10 is a plan view of the end portions and the anisotropic conductive resin layer according to a first modification, as viewed from the first thickness direction. While the anisotropic conductive resin layer 5A (divided anisotropic conductive resin layers 7) according to the second embodiment is formed by removing part of the sheet-like anisotropic conductive resin by a laser or the like, the present disclosure is not limited thereto. For example, as illustrated in FIG. 10, an anisotropic conductive resin layer 5B according to the first modification includes a plurality of divided anisotropic conductive resin layers 7 and extending portions 8 that couple the divided anisotropic conductive resin layers 7 before being disposed on the first coupling terminals 41 and the end portions 20. When the flexible printed circuit board 102 is pressure-bonded to the divided anisotropic conductive resin layers 7, the extending portions 8 are not crushed by the flexible printed circuit board 102. Therefore, the conductive particles 6 in the extending portions 8 are separated from each other and do not constitute a conductive path. The anisotropic conductive resin layer 5B according to the first modification can be fabricated without the process of removing part of the anisotropic conductive resin by a laser or the like.

### Third Embodiment

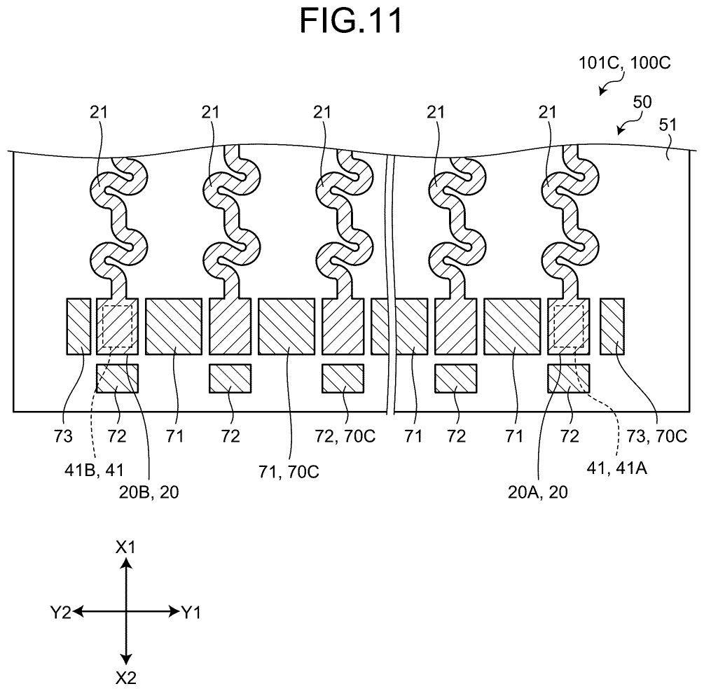

FIG. 11 is a plan view of the end portions and the dummy end portions according to a third embodiment, as viewed from the first thickness direction. A stretchable substrate 101C of a stretchable device 100C according to a third embodiment is different from the first embodiment in that it includes a dummy end portion 70C instead of the dummy end portion 70.

The dummy end portion 70C includes the first dummy end portions 71, second dummy end portions 72, and third dummy end portions 73. The first dummy end portions 71 are disposed between the end portions. The second dummy end portions 72 are disposed in the second longitudinal direction X2 (second side in the longitudinal direction) with respect to the end portions. The third dummy end portions 73 are disposed closest to the ends in the intersecting direction. The second dummy end portion 72 can prevent the anisotropic conductive resin layer 5 stacked on the first coupling terminal 41 and the end portion 20 from flowing (moving) toward the second longitudinal direction X2.

The third dummy end portions 73 include a third dummy end portion 73A and a third dummy end portion 73B. The third dummy end portion 73A is disposed in the first intersecting direction Y1 with respect to an end portion 20A disposed closest to the end in the first intersecting direction Y1 out of the end portions. The third dummy end portion 73B is disposed in the second intersecting direction Y2 with respect to an end portion 20B disposed closest to the end in the second intersecting direction Y2. The third dummy end portion 73A can prevent the anisotropic conductive resin layer 5 stacked on the first coupling terminal 41A and the end portion 20A disposed closest to the end in the first intersecting direction Y1 from flowing (moving) toward the first intersecting direction Y1. The third dummy end portion 73B can prevent the anisotropic conductive resin layer 5 stacked on the first coupling terminal 41B and the end portion 20B disposed closest to the end in the second intersecting direction Y2 from flowing (moving) toward the second intersecting direction Y2.

According to the third embodiment, the number of conductive particles interposed between the first coupling terminal 41 and the second coupling terminal 104 is greater than in the first and the second embodiments. Therefore, the electrical coupling between the first coupling terminal 41 and the second coupling terminal 104 is further stabilized.

While the end portions 20 according to the embodiments and the modification described above are arrayed in the intersecting direction, the present disclosure is not limited thereto. The following fourth embodiment describes an example where the arrangement of the end portions 20 is modified.

### Fourth Embodiment

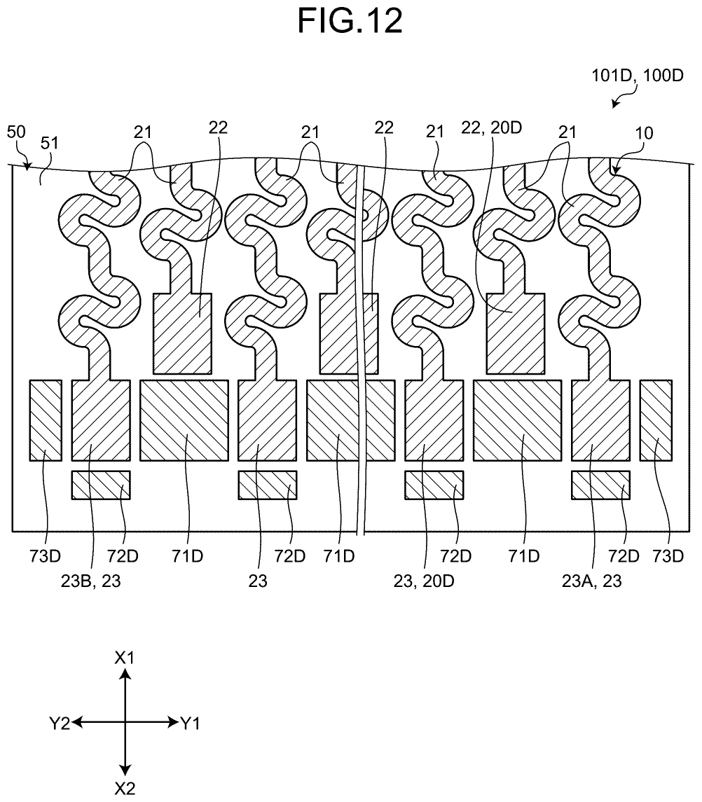

FIG. 12 is a plan view of the end portions and the dummy end portions according to the fourth embodiment, as viewed from the first thickness direction. A stretchable substrate 101D of a stretchable device 100D according to the fourth embodiment is different from the first embodiment in that a plurality of end portions 20D are displaced in the longitudinal direction. The end portions 20D include a plurality of first end portions 22 and a plurality of second end portions 23. The first end portions 22 are spaced apart in the intersecting direction. The second end portions 23 are disposed between the first end portions 22. The second end portions 23 are disposed in the second longitudinal direction X2 with respect to the first end portions 22.

A dummy end portion 70D according to the fourth embodiment includes first dummy end portions 71D, second dummy end portions 72D, and third dummy end portions 73D. The first dummy end portions 71D are disposed between the second end portions 23. Thus, the first dummy end portions 71D are disposed in the second longitudinal direction X2 with respect to the first end portions 22. Therefore, the first dummy end portion 71D prevents the anisotropic conductive resin layer 5 from moving to the space between the second end portions 23 and also prevents the anisotropic conductive resin layer 5 from moving in the second longitudinal direction X2 from the first end portion 22.

The second dummy end portions 72D are disposed in the second longitudinal direction X2 with respect to the second end portions 23. Therefore, the second dummy end portion 72D prevents the anisotropic conductive resin layer 5 from moving in the second longitudinal direction X2 from the second end portion 23.

Two third dummy end portions 73D are provided. One of the third dummy end portions 73D is disposed in the first intersecting direction Y1 with respect to a second end portion 23A disposed closest to the end in the first intersecting direction Y1 out of the second end portions 23. The other of the third dummy end portions 73D is disposed in the second intersecting direction Y2 with respect to the end portion 20B disposed closest to the end in the second intersecting direction Y2. Therefore, the one of the third dummy end portions 73D prevents the anisotropic conductive resin layer 5 from moving in the first intersecting direction Y1 from the second end portion 23A. The other of the third dummy end portions 73D prevents the anisotropic conductive resin layer 5 from moving in the second intersecting direction Y2 from the second end portion 23B.

While the dummy end portion according to the embodiments and the modification are divided into a plurality of dummy end portions, the dummy end portion according to the present disclosure may be obtained by integrating the plurality of dummy end portions described in the embodiments and the modification. While the electrical circuit included in the array layer 30 according to the embodiments is the load detection circuit that measures loads in the longitudinal direction and the intersecting direction of the stretchable substrate 101, the electrical circuit according to the present disclosure may be other circuits.

What is claimed is:

1. A stretchable device comprising:
a stretchable substrate comprising a first resin layer, a resin base member, an array layer, and a second resin layer stacked in the order as listed; and
a flexible printed circuit board electrically coupled to an electrical circuit included in the array layer, wherein
the resin base member comprises a plurality of end portions separated from each other,
the electrical circuit comprises a plurality of first coupling terminals disposed on the end portions,
the flexible printed circuit board comprises a plurality of second coupling terminals facing the first coupling terminals,
an anisotropic conductive resin layer electrically coupling the first coupling terminals to the second coupling terminals is provided between the first coupling terminals and the second coupling terminals, and
the first resin layer has:
a first surface provided with the resin base member; and
a dummy end portion provided to the first surface and disposed around the end portions.

2. The stretchable device according to claim 1, wherein
the resin base member comprises coupling hinges extending along the first surface,
ends of the coupling hinges in a longitudinal direction in which the coupling hinge extends are coupled to the end portions,
the end portions are spaced apart in an intersecting direction parallel to the first surface and intersecting the longitudinal direction, and
the dummy end portion is disposed between the end portions adjacently disposed in the intersecting direction.

3. The stretchable device according to claim 2, wherein
each of the coupling hinges is disposed on a first side of a corresponding one of the end portions in the longitudinal direction, and
the dummy end portion is disposed on a second side of each of the end portions in the longitudinal direction.

4. The stretchable device according to claim 1, wherein
the resin base member comprises coupling hinges extending along the first surface,
each of the coupling hinges is disposed on a first side of a corresponding one of the end portions in a longitudinal direction in which the coupling hinge extends,
ends of the coupling hinges in the longitudinal direction are coupled to the end portions,
the end portions include:
a plurality of first end portions spaced apart in an intersecting direction parallel to the first surface and intersecting the longitudinal direction; and
a plurality of second end portions disposed between the first end portions,
the second end portions are disposed on a second side in the longitudinal direction with respect to the first end portions, and
the dummy end portion is disposed between the second end portions and on the second side of the first end portions in the longitudinal direction.

5. The stretchable device according to claim 1, wherein the anisotropic conductive resin layer is disposed over each of the first surface, the end portions, and the first coupling terminals.

6. The stretchable device according to claim 1, wherein the anisotropic conductive resin layer is disposed only on the end portions and the first coupling terminals.
